(19) United States
(12) Patent Application Publication
(10) Pub. No.: US 2017/0342548 A1
(43) Pub. Date: Nov. 30, 2017

(54) METHOD OF FORMING CARBON FILM, APPARATUS OF FORMING CARBON FILM AND STORAGE MEDIUM

(71) Applicant: TOKYO ELECTRON LIMITED, Tokyo (JP)

(72) Inventors: Akira SHIMIZU, Nirasaki City (JP); Masayuki KITAMURA, Nirasaki City (JP); Yosuke WATANABE, Nirasaki City (JP); Akinobu KAKIMOTO, Nirasaki City (JP)

(21) Appl. No.: 15/599,622

(22) Filed: May 19, 2017

(30) Foreign Application Priority Data
May 24, 2016 (JP) 2016-103494

(51) Int. Cl. C23C 16/02; C23C 16/26; C23C 16/52; H01L 21/285

(52) U.S. Cl. CPC C23C 16/0272; H01L 21/28556; C23C 16/26; C23C 16/52

(57) ABSTRACT

There is provided a method of forming a carbon film on a workpiece, which includes: loading the workpiece into a process chamber, and supplying a hydrocarbon-based carbon source gas and a pyrolysis temperature drop gas for dropping a pyrolysis temperature of the hydrocarbon-based carbon source gas into the process chamber, pyrolyzing the hydrocarbon-based carbon source gas by heating the hydrocarbon-based carbon source gas at a temperature lower than a pyrolysis temperature of the hydrocarbon-based carbon source gas, and forming the carbon film on the workpiece by a thermal CVD method. An iodine-containing gas is used as the pyrolysis temperature drop gas.

### CROSS-REFERENCE TO RELATED APPLICATION

This application claims the benefit of Japanese Patent Application No. 2016-103494, filed on May 24, 2016, in the Japan Patent Office, the disclosure of which is incorporated herein in its entirety by reference.

### TECHNICAL FIELD

The present disclosure relates to a method of forming a carbon film, an apparatus of forming a carbon film and a non-transitory computer-readable storage medium.

### BACKGROUND

Carbon is getting a lot of attention as one of the materials used in a patterning process of a next-generation semiconductor device. In such a patterning process, a good buriability for a stepped shape is required.

As a film forming method which obtains such a good buriability for a stepped shape, a coating method has been studied but there is a problem in heat resistance.

Meanwhile, a plasma CVD method or a thermal CVD method has been generally known as a method of forming a carbon film.

However, in the case of forming a carbon film using the plasma CVD method, a film formation temperature may be kept at a low level (in a range of 100 to 500 degrees C. in the related art), but step coverage is poor. As such, the plasma CVD method may not be suitable for forming a carbon film on an underlying film having irregularities such as a line pattern, a hole pattern or the like.

In addition, in the case of forming a carbon film using the thermal CVD method, a step coverage is relatively good, but a film formation temperature needs to be kept at a high level (in a range of 800 to 1,000 degrees C. in the related art). Even if film formation conditions are optimized, there is a limit that the film formation temperature falls within a range of 600 to 800 degrees C. For example, in view of a thermal history with respect to a transistor formed on a silicon wafer, the plasma CVD method may not be suitable for use in a process applied to an upper layer portion of a semiconductor device.

In this regard, it has been proposed that a pyrolysis temperature drop gas is used to drop a pyrolysis temperature, when forming a carbon film by a thermal CVD method which achieves a good step coverage with respect to a hydrocarbon-based carbon source gas used as a film-forming raw material. Specifically, there is known a technique which drops a pyrolysis temperature using a Cl₂ gas as a pyrolysis temperature drop gas and lowers a film formation temperature to about 300 to 500 degrees C.

However, it has been confirmed that, in the case of using the Cl₂ gas as the pyrolysis temperature drop gas, when the film formation temperature reaches 350 degrees C. or higher, specifically, 450 degrees C. or higher, an underlying silicon film is damaged due to etching caused by the Cl₂ gas. In addition, it has been confirmed that, in the case of forming a film on an Si film, there is a possibility that adhesivity deteriorates to such a degree that a film peeling is invoked even in a film thickness of about 10 nm.

### SUMMARY

Some embodiments of the present disclosure provide a carbon film forming method and a carbon film forming apparatus, which are capable of suppressing damage to an underlying film and forming a carbon film with good adhesivity, in a case where a film formation is performed at a low temperature using a pyrolysis temperature drop gas, and a non-transitory computer-readable storage medium for implementing the method.

According to one embodiment of the present disclosure, there is provided a method of forming a carbon film on a workpiece, which includes: loading the workpiece into a process chamber; and supplying a hydrocarbon-based carbon source gas and a pyrolysis temperature drop gas for dropping a pyrolysis temperature of the hydrocarbon-based carbon source gas into the process chamber, pyrolyzing the hydrocarbon-based carbon source gas by heating the hydrocarbon-based carbon source gas at a temperature lower than a pyrolysis temperature of the hydrocarbon-based carbon source gas, and forming the carbon film on the workpiece by a thermal CVD method. An iodine-containing gas is used as the pyrolysis temperature drop gas.

According to another embodiment of the present disclosure, there is provided an apparatus of forming a carbon film on a workpiece, which includes: a process chamber configured to accommodate the workpiece on which the carbon film is to be formed; a process gas supply mechanism configured to supply a process gas into the process chamber; a heating device configured to heat the workpiece accommodated in the process chamber, a loading mechanism configured to load the workpiece into the process chamber, and a control part configured to control the process gas supply mechanism, the heating device, and the loading mechanism such that the aforementioned method is performed.

According to another embodiment of the present disclosure, there is provided a non-transitory computer-readable storage medium storing a program that operates on a computer and controls a carbon film forming apparatus, wherein the program, when executed, causes the computer to control the carbon film forming apparatus so as to perform the aforementioned method.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically illustrating one example of a film forming apparatus capable of performing a film forming method of the present disclosure.

FIG. 2 is a flowchart illustrating a flow of a carbon film forming method according to one embodiment of the present disclosure.

FIGS. 3A to 3C are process cross-sectional views when performing the carbon film forming method according to one embodiment of the present disclosure.

FIGS. 4A and 4B are views illustrating a comparison between a reaction model in a case where a Cl₂ gas is used as a pyrolysis temperature drop gas and a reaction model in a case where an iodine-containing gas is used as a pyrolysis temperature drop gas

FIG. 5 is a cross-sectional view illustrating a layer structure of Sample A in Experimental example 1.

FIG. 6 is a cross-sectional view illustrating a layer structure of Sample B in Experimental example 1.

FIG. 7 is an SEM photograph of Sample A in Experimental example 1.

FIG. 8 is an SEM photograph of Sample B in Experimental example 1.

FIG. 9 is a view illustrating film composition ratios and film densities of carbon films in Samples A, B and C of Experimental example 2.

FIG. 10 is a view illustrating a concentration of iodine in a carbon film, which is obtained using SIMS in Samples B and C of Experimental example 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

The present inventor's conducted research over and over to solve the aforementioned problems. Consequently, the present inventor's found the facts that, by using an iodine-containing gas as a phyrolysis temperature drop gas, it is possible to confirm a behavior completely different from that when using a Cl₂ gas, and to drastically reduce an amount of halogen contained in a film, without causing damage to an underlying film and degradation of adhesivity.

### <One Example of Apparatus for Embodying the Present Disclosure>

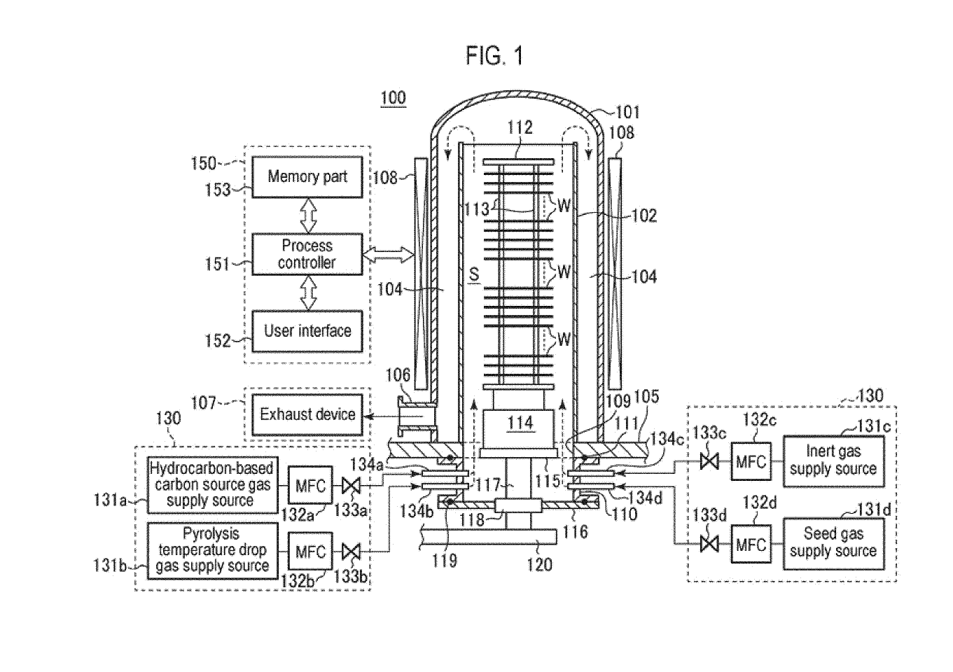

FIG. 1 is a cross-sectional view schematically illustrating one example of a film forming apparatus capable of performing a film forming method of the present disclosure.

As illustrated in FIG. 1, a film forming apparatus 100 is configured as a vertical batch-type film forming apparatus, and includes a cylindrical outer wall 101 with a ceiling and a cylindrical inner wall 102 installed inside the outer wall 101. The outer wall 101 and the inner wall 102 are made of, for example, quartz. An inner area of the inner wall 102 is defined as a process chamber S in which a plurality of semiconductor wafers W (hereinafter, simply referred to as “wafers”) as workpieces are processed in batches.

The outer wall 101 and the inner wall 102 are spaced apart from each other in a horizontal direction with an annular space 104 defined between the outer wall 101 and the inner wall 102. A lower end portion of each of the outer wall 101 and the inner wall 102 is bonded to a base member 105. An upper end portion of the inner wall 102 is spaced apart from the ceiling of the outer wall 101 so that an upper side of the process chamber S communicates with the annular space 104. The annular space 104 communicating with the upper side of the process chamber S serves as an exhaust path. A gas supplied to and spread in the process chamber S flows from a lower side of the process chamber S to the upper side thereof so as to be sucked into the annular space 104. An exhaust pipe 106 is connected to, for example, a lower end portion of the annular space 104, and is connected to an exhaust device 107. The exhaust device 107 is configured to include a vacuum pump or the like, exhausts the process chamber S, and adjusts an internal pressure of the process chamber S to have a pressure adapted for a process.

A heating device 108 is installed to surround the process chamber S outside the outer wall 101. The heating device 108 adjusts an internal temperature of the process chamber S to have a temperature adapted for a process, and heats the plurality of wafers W in batches.

The lower side of the process chamber S communicates with an opening 109 formed in the base member 105. A cylindrical manifold 110 formed of, for example, stainless steel is connected to the opening 109 via a seal member 111 such as an O-ring or the like. A lower end portion of the manifold 110 is opened. Through this opening, a wafer boat 112 is inserted into the process chamber S. The wafer boat 112 is made of, for example, quartz, and has a plurality of posts 113. Grooves (not shown) are formed in each of the posts 113. A plurality of substrates to be processed is supported by the grooves in a lump. Thus, the plurality of, e.g., 50 to 150 wafers, as the substrates to be processed, can be mounted in the wafer boat 112 in multiple stages. The wafer boat 112 with the plurality of wafers W mounted therein is inserted into the process chamber S so that the plurality of wafers W can be accommodated in the process chamber S.

The wafer boat 112 is placed on a table 115 via a heat-insulating tube 114 made of quartz. The table 115 is supported on a rotary shaft 117 that penetrates through a lid portion 116 made of, for example, stainless steel. The lid portion 116 opens and closes an opening defined at the lower end portion of the manifold 110. For example, a magnetic fluid seal 118 is installed in the penetration portion of the lid portion 116 to hermetically seal and rotatably support the rotary shaft 117. Furthermore, a seal member 119 configured as, for example, an O-ring is installed between a peripheral portion of the lid portion 116 and the lower end portion of the manifold 110 to maintain a sealing property of the interior of the process chamber S. The rotary shaft 117 is installed at a front end of an arm 120 supported by an elevating mechanism (not shown) such as, for example, a boat elevator or the like. Thus, the wafer boat 112, the lid portion 116 and the like are integrally moved up and down in a vertical direction so as to be inserted into and extracted from the process chamber S.

The film forming apparatus 100 includes a process gas supply mechanism 130 configured to supply a gas used for a process, into the process chamber S.

The process gas supply mechanism 130 in this embodiment includes a hydrocarbon-based carbon source gas supply source 131a, a pyrolysis temperature drop gas supply source 131b, an inert gas supply source 131c, and a seed gas supply source 131d.

The hydrocarbon-based carbon source gas supply source 131a is coupled to a gas supply port 134a through a mass flow controller (MFC) 132a and an opening/closing valve 133a. Similarly, the pyrolysis temperature drop gas supply source 131b is coupled to a gas supply port 134b through a mass flow controller (MFC) 132b and an opening/closing valve 133b. The inert gas supply source 131c is coupled to a gas supply port 134c through a mass flow controller (MFC) 132c and an opening/closing valve 133c. The seed gas supply source 131d is coupled to a gas supply port 134d through a mass flow controller (MFC) 132d and an opening/closing valve 133d. Each of the gas supply ports 134a to 134d is installed to penetrate through a sidewall of the manifold 110 in a horizontal direction, and spreads a gas supplied thereto toward the interior of the process chamber S defined above the manifold 110.

A hydrocarbon-based carbon source gas supplied from the hydrocarbon-based carbon source gas supply source 131a is to form a carbon film by a thermal CVD method.

Examples of the hydrocarbon-based carbon source gas may include a hydrocarbon-containing gas expressed as at least one of the following molecular formulas:

CₙH₂ₙ₊₂;

CₘH₂ₘ; and

CₘH₂ₘ₋₂
(where n is a natural number of one or more and m is a natural number of two or more).

In some embodiments, an example of the hydrocarbon-based carbon source gas may include a benzene gas (C₆H₆).

Examples of hydrocarbon expressed as the molecular formula CₙH₂ₙ₊₂ may include:
Methane gas (CH₄);
Ethane gas (C₂H₆);
Propane gas (C₃H);
Butane gas (C₄H₁₀: also containing other isomer);
Pentane gas (C₅H₁₂: also containing other isomer); and the like.

Examples of hydrocarbon expressed as the molecular formula CₘH₂ₘ may include:
Ethylene gas (C₂H₄);
Propylene gas (C₃H₆: also containing other isomer);
Butylene gas (C₄H₈: also containing other isomer);
Pentene gas (C₅H₁₀: also containing other isomer); and the like.

Examples of hydrocarbon expressed as the molecular formula CₘH₂ₘ₋₂ may include:
Acetylene gas (C₂H₂);
Propyne gas (C₃H₄: also containing other isomer);
Butadiene gas (C₄H₆: also containing other isomer);
Isoprene gas (C₅H₈: also containing other isomer); and the like.

An iodine-containing gas is used as the pyrolysis temperature drop gas supplied from the pyrolysis temperature drop gas supply source 131b. The iodine-containing gas has a function of dropping the pyrolysis temperature of the hydrocarbon-based carbon source gas using its catalyst function to lower a film formation temperature of the carbon film by the thermal CVD method.

As the iodine-containing gas, it may be possible to use an organic iodine compound. Hydrocarbon iodide such as methyl iodide (CH₃I), ethyl iodide (C₂H₅I), isopropyl iodide (C₃H₇I) or the like may be used as the organic iodine compound. Alternatively, an oxygen-containing gas such as ethyl iodine acetate (ICH₂COOC₂H₅) or the like may be used as the organic iodine compound.

An inert gas supplied from the inert gas supply source 131c is used as a purge gas or a dilution gas. As the inert gas, it may be possible to use, for example, a noble gas such as an N₂ gas, an Ar gas or the like.

A seed gas supplied from the seed gas supply source 131d serves to form a seed layer, before forming a carbon film. The seed layer is formed to shorten an incubation time of the carbon film. As the seed gas, it may be possible to use an aminosilane-based gas. The aminosilane-based gas may include butylaminosilane (BAS), bis-tertiary-butylaminosilane (BTBAS), dimethylaminosilane (DMAS), bis-dimethylaminosilane (BDMAS), trisdimethylaminosilane (TDMAS), diethylaminosilane (DEAS), bis-diethylaminosilane (BDEAS), di-propylaminosilane (DPAS), diisopropylaminosilane (DIPAS), and the like. Furthermore, the supply of the seed gas is not essential.

The film forming apparatus 100 includes a control part 150. The control part 150 includes a process controller 151 configured as, for example, a microprocessor (computer). Respective components of the film forming apparatus 100 are controlled by the process controller 151. A user interface 152 and a memory part 153 are connected to the process controller 151.

The user interface 152 includes an input part provided with a touch panel display, a keyboard or the like for performing an input operation or the like of a command in order to manage the film forming apparatus 100 by an operator, and a display part including a display or the like for visually displaying an operation state of the film forming apparatus 100.

The memory part 153 stores a so-called process recipe including a control program for realizing various kinds of processes to be executed by the film forming apparatus 100 under the control of the process controller 151 or a program for causing each of the respective components of the film forming apparatus 100 to execute a process according to process conditions. The process recipe is stored in a storage medium of the memory part 153. The storage medium may be a hard disk or a semiconductor memory, or may be a portable one such as a CD-ROM, a DVD, a flash memory or the like. Furthermore, the process recipe may be suitably transmitted from another device, for example, via a dedicated line.

If necessary, the process recipe is read from the memory part 153 by an operator's instruction or the like inputted from the user interface 152. The process controller 151 causes the film forming apparatus 100 to execute a process according to the read process recipe.

### <Method of Forming Carbon Film>

Next, one embodiment of a carbon film forming method of the present disclosure, which is implemented by the film forming apparatus of FIG. 1, will be described.

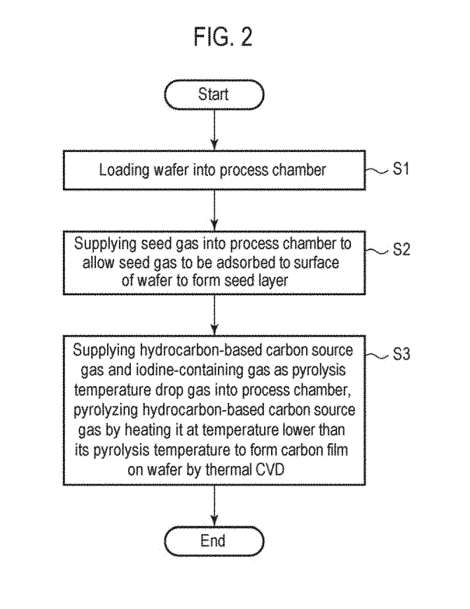

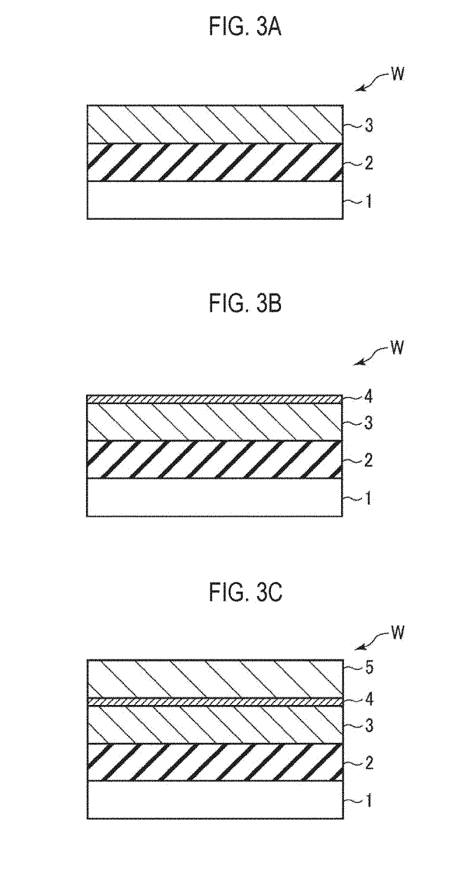

FIG. 2 is a flowchart illustrating a flow of the carbon film forming method according to one embodiment of the present disclosure, and FIGS. 3A to 3C are process cross-sectional views when implementing the carbon film forming method.

First, for example, as illustrated in FIG. 3A, a plurality of e.g., 50 to 150 wafers W, in which a silicon oxide film 2 is formed on a silicon substrate 1 with a predetermined structure (not shown) formed thereon, and an amorphous silicon film 3 is formed on the silicon oxide film 2, is mounted in the wafer boat 112. The wafer boat 112 is inserted into the process chamber S of the film forming apparatus 100 from below such that the plurality of wafers W is loaded into the process chamber S (step S1). Then, the lower end opening of the manifold 110 is closed by the lid portion 116 so that the interior of the process chamber S becomes a sealed space. In this state, the interior of the process chamber S is vacuum-exhausted to maintain a predetermined depressurized atmosphere. The supply of the electric power to the heating device 108 is controlled to increase a wafer temperature, thus maintaining a process temperature while rotating the wafer boat 112.

In this state, the seed gas supply source 131d initially supplies a seed gas, for example, an aminosilane-based gas, to adsorb the same onto a surface of the wafer (onto the amorphous silicon film 3). Thus, a seed layer 4 for shortening the incubation time of the carbon film is formed (step S2, FIG. 3B). However, the formation of the seed layer 4 is not essential.

Subsequently, after purging the interior of the process chamber S, a process of forming a carbon film 5 is performed by a thermal CVD which does not use a plasma assist (step S3, FIG. 3C).

In the film forming process of the carbon film using the thermal CVD of step S3, as the hydrocarbon-based carbon source gas supplied from the hydrocarbon-based carbon source gas supply source 131a, a hydrocarbon-containing gas, for example, a C₅H₈ gas, is supplied into the process chamber S. As a pyrolysis temperature drop gas supplied from the pyrolysis temperature drop gas supply source 131b, an iodine-containing gas, for example, an ethane iodide (C₂H₅I) gas, is supplied into the process chamber S. By heating and pyrolyzing the hydrocarbon-based carbon source gas at a predetermined temperature lower than a respective pyrolysis temperature, the carbon film 5 is formed on the surface of the wafer W by the thermal CVD.

Once the formation of the carbon film is completed, the process chamber S is exhausted by the exhaust device 107, and a purge gas, for example, an N₂ gas, is supplied from the inert gas supply source 131c into the process chamber S to purge the process chamber S. Thereafter, the process chamber S is returned to an atmospheric pressure, and subsequently, the wafer boat 112 is moved down to unload the wafers W from the process chamber S.

In the present embodiment, the carbon film is formed by dropping a pyrolysis temperature of the hydrocarbon-based carbon source gas using the pyrolysis temperature drop gas exhibiting a catalyst effect up to a temperature lower than the pyrolysis temperature of the carbon source gas. That is to say, it is possible to lower the temperature of 600 degrees C. or higher (in a range of 800 to 1,000 degrees C. in the related art, specifically, a range of 600 to 800 degrees C. for the optimization of the conditions), which is conventionally required for forming the carbon film in the thermal CVD method using the hydrocarbon-based carbon source gas, to a lower temperature, thus forming the carbon film at a low temperature of about 300 degrees C.

However, in the aforementioned related art, a gas containing a halogen gas has been described to be used as the pyrolysis temperature drop gas and the gas has been described to preferably contain only a halogen element rather than a compound gas. In practice, an example using a Cl₂ gas has been described. Furthermore, in the aforementioned related art, there is disclosed on an effect of extracting hydrogens (H) from a hydrocarbon-based carbon source gas (CₓH_{y}), for example, an ethylene gas (C₂H₄), using the Cl₂ gas as the pyrolysis temperature drop gas, and decomposing the ethylene gas. That is to say, when a carbon film is formed, a halogen element such as chlorine (Cl) is exhausted as, for example, HCl, by desorbing H existing in a surface layer. Thus, the desorption of H generates a dangling bond, which contributes to the film formation process.

However, in the case of using the Cl₂ gas as the pyrolysis temperature drop gas, it was confirmed that, if the film formation temperature reaches 350 degrees C. or higher, specifically, 400 degrees C. or higher, there is a possibility that a underlying amorphous silicon film is damaged due to etching caused by the Cl₂ gas and adhesivity deteriorates to such an extent that a film peeling occurs even in a film thickness of about 10 nm.

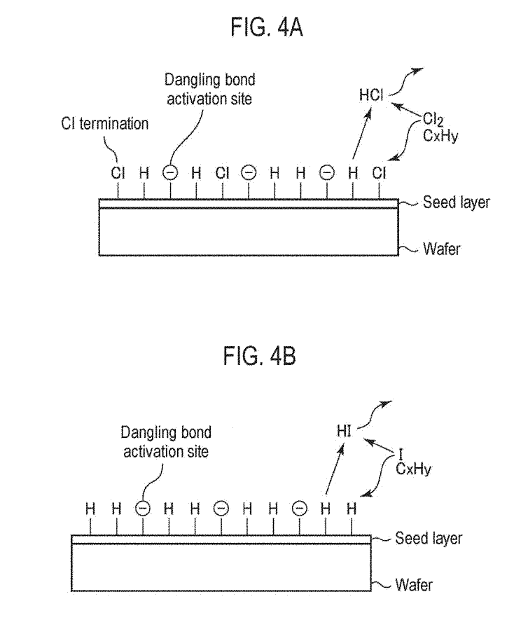

That is to say, when the Cl₂ gas is used as the pyrolysis temperature drop gas, since Cl has high reactivity, an underlying film may be damaged depending on a material thereof, for example, in the case where the underlying film is formed of silicon in this embodiment. In addition, as illustrated in FIG. 4A, the high reactive Cl easily terminates the dangling bond. Thus, dangling bond activation sites as carbon adsorption sites are reduced to degrade adsorption of C, which results in degradation of adhesivity even if a film thickness is thin at a level of about 10 nm.

In contrast, in the present embodiment, the iodine-containing gas, specifically, an iodine compound, is used as the pyrolysis temperature drop gas. This eliminates damage to the underlying film or the degradation of adhesivity. That is to say, since iodine (I) has reactivity lower than that of Cl, the iodine-containing gas, specifically, the iodine compound gas, causes a milder reaction than a chlorine-containing gas such as Cl₂ gas or the like, which causes less damage to the underlying film. Furthermore, as illustrated in FIG. 4B, since it is hard to terminate the low reactive dangling bond, dangling bond activation sites serving as carbon adsorption sites are not substantially reduced so that the degradation of adhesivity of the carbon film due to degradation of adsorption hardly occurs. Thus, it is possible to form a thick carbon film with a good adhesivity, irrespective of the underlying film.

In addition, as described above, since the iodine-containing gas causes the mild reaction, in the case where the Cl₂ gas is used as the pyrolysis temperature drop gas, it is possible to form the carbon film without entailing such a problem even at a temperature of 400 degrees C. or higher at which the damage to the underlying silicon film or the degradation of adhesivity is caused. It is therefore possible to widen the range of the film formation temperature to about 600 degrees C. Thus, the present disclosure can be applied to a process in which a wide range of film formation temperature is required.

Furthermore, in the case of using the Cl₂ gas as the pyrolysis temperature drop gas, as mentioned above, since Cl easily terminates a dangling bond, Cl is contained in the carbon film at a level of about 15 at %. In contrast, in the case of using the iodine-containing gas as the pyrolysis temperature drop gas, as mentioned above, it is hard to terminate a dangling bond with iodine which is hard to contain in a film with a great atomic weight. Thus, it is possible to lower a concentration of iodine in the film up to an impurity level. It is therefore possible to form a highly purified carbon film with less halogen elements as impurities.

As described above, in view of reactivity or the like, the iodine compound, specifically, the organic iodine compound may be used as the iodine-containing gas. On the other hand, in view of minimizing impurity, hydrocarbon iodide, for example, ethyl iodide (C₂H₅I) may be used as the iodine-containing gas.

The desirable conditions in forming the carbon film at step 3 are as follows.
Film formation temperature: 300 to 600 degrees C. (specifically, 350 to 400 degrees C.)
Internal pressure of process chamber: 1 to 200 Torr (133 to 26,600 Pa)
Flow rate of hydrocarbon-based carbon source gas: 100 to 2,000 sccm (mL/min)
Flow rate of pyrolysis temperature drop gas (iodine-containing gas): 10 to 200 sccm (mL/min)
Flow rate ratio (partial pressure ratio) of hydrocarbon-based carbon source gas to iodine-containing gas: 20 to 200
Film thickness of carbon film: 2.0 to 500 nm

Examples of actual manufacturing conditions are as follows:
Hydrocarbon-based carbon source gas: butadiene (C₄H₆)
Pyrolysis temperature drop gas: ethyl iodide (C₂H₅I)
Gas flow rate ratio: C₄H/C₂H₅I=1,000/50 sccm
Film formation temperature: 350 degrees C.
Internal pressure of process chamber: 95 Torr (12,666.6 Pa)
Film thickness of carbon film: 40 nm

### EXPERIMENTAL EXAMPLES

Next, experimental examples will be described.

### Experimental Example 1

Experimental example 1 was performed to confirm adhesivity of a carbon film with respect to Sample A having a carbon film formed using butadiene (C₄H₆) as a hydrocarbon-based carbon source gas and using a Cl₂ gas as a pyrolysis temperature drop gas, and Sample B having a carbon film formed using butadiene (C₄H₆) as the hydrocarbon-based carbon source gas and using an ethyl iodide (C₂H₅I) gas as the pyrolysis temperature drop gas.

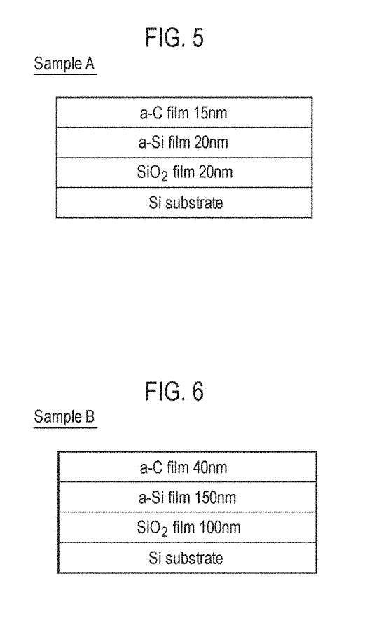

For Sample A, as illustrated in FIG. 5, an amorphous carbon (a-C) film having a thickness of 15 nm was formed on a wafer in which an SiO₂ film having a thickness of 10 nm and an amorphous silicon (a-Si) film having a thickness of 20 nm are sequentially formed on a silicon substrate, under the following conditions.
Flow rate of C₄H₆ gas: 100 sccm
Flow rate of Cl₂ gas: 50 sccm
Film formation temperature: 350 degrees C.
Internal pressure of process chamber: 1.5 Torr (200 Pa)

For Sample B, as illustrated in FIG. 6, an amorphous carbon (a-C) film having a thickness of 40 nm was formed on a wafer in which an SiO₂ film having a thickness of 100 nm and an amorphous silicon (a-Si) film having a thickness of 150 nm are sequentially formed on a silicon substrate, under the following conditions.
Flow rate of C₄H₆ gas: 1,000 sccm
Flow rate of C₂H₅I gas: 50 sccm
Film formation temperature: 350 degrees C.
Internal pressure of process chamber: 95 Torr (12,666.6 Pa)

For these Samples A and B, the adhesivity of the carbon films was confirmed through SEM photographs.

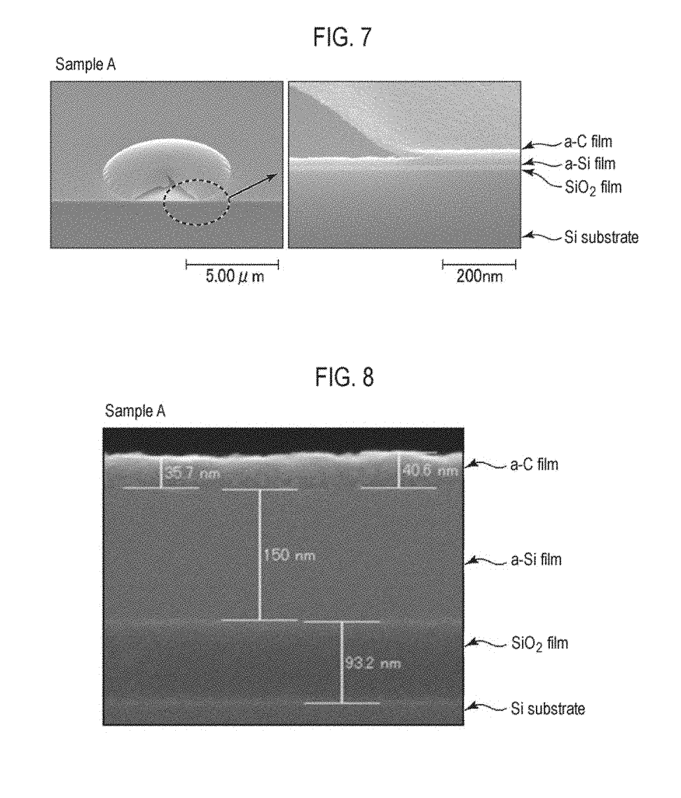

From FIG. 7 showing an SEM photograph of Sample A, it can be seen that the adhesivity of the carbon film is poor, which causes a partial film peeling. In contrast, from FIG. 8 showing an SEM photograph of Sample B, it can be seen that the adhesivity of the carbon film is good, even though the carbon film has the thickness of 40 nm greater than that of Sample A. Furthermore, in Sample B, the carbon film was formed over the entire surface with good adhesivity.

### Experimental Example 2

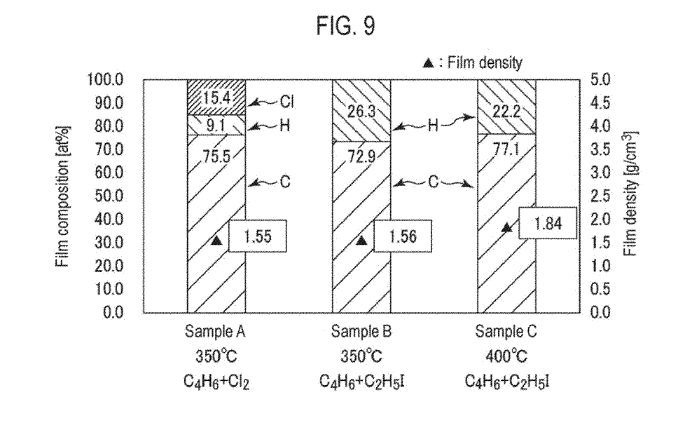

Experimental example 2 was performed to measure a film composition ratio and a film density of a carbon film by RBS-HFS with respect to Samples A and B, and Sample C similar to Sample B, except that the film formation temperature was set at 400 degrees C. The results are illustrated in FIG. 9.

As illustrated in FIG. 9, in Sample A using the Cl₂ gas as the pyrolysis temperature drop gas, a concentration of Cl as a halogen element in the carbon film was 15.4 at %, whereas in each of Samples B and C using C₂H₅I as the pyrolysis temperature drop gas, a concentration of I as a halogen element in the carbon film was not detected. Furthermore, the film densities of the carbon films of Samples A and B in which the films were formed at 350 degrees C. were respectively 1.55 g/cm³ and 1.56 g/cm³, which are substantially the same level. However, in Sample C in which the film formation temperature is at a high level of 400 degrees C., the film density was at a high level of 84 g/cm³.

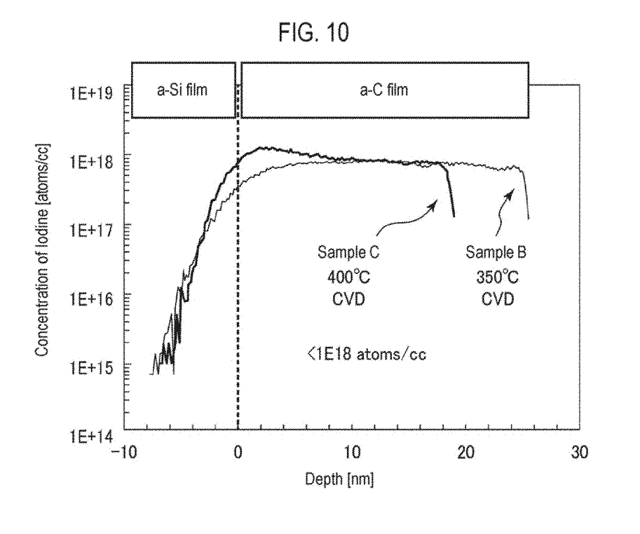

For each of Samples B and C, the concentration of iodine in the carbon film was measured by a secondary ion mass spectroscopy (SIMS). The results are illustrated in FIG. 10. As illustrated in FIG. 10, it was confirmed that the concentrations of iodine in both Samples B and C were substantially 1E18 (atoms/cc) or less and the concentrations of iodine in the films were at an impurity level.

### Other Applications

While some embodiments of the present disclosure have been described above, the present disclosure is not limited to the aforementioned embodiments but may be differently modified without departing from the spirit of the disclosures.

For example, in the aforementioned embodiments, there has been described an example in which the carbon film is formed using the vertical type batch-type film forming apparatus, but a single wafer-type film forming apparatus may be used or a batch-type film forming apparatus other than the vertical type one may also be used.

Furthermore, in the aforementioned embodiments, there has been described an example in which the semiconductor wafer is used as the workpiece but not limited to the semiconductor wafer. Needless to say, the present disclosure may be applied even to a glass substrate used in a flat panel display (FPD) such as a liquid crystal display or the like or other workpieces such as a ceramic substrate or the like.

According to some embodiments of the present disclosure, it is possible to suppress damage to an underlying film and form a carbon film with good adhesivity, using an iodine-containing gas as a phyrolysis temperature drop gas. Further, it is possible to drastically reduce an amount of halogen contained in a film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a carbon film on a workpiece, comprising:
loading the workpiece into a process chamber; and
supplying a hydrocarbon-based carbon source gas and a pyrolysis temperature drop gas for dropping a pyrolysis temperature of the hydrocarbon-based carbon source gas into the process chamber, pyrolyzing the hydrocarbon-based carbon source gas by heating the hydrocarbon-based carbon source gas at a temperature lower than a pyrolysis temperature of the hydrocarbon-based carbon source gas, and forming the carbon film on the workpiece by a thermal CVD method,
wherein an iodine-containing gas is used as the pyrolysis temperature drop gas.

2. The method of claim 1, wherein the pyrolysis temperature drop gas is an iodine compound.

3. The method of claim 2, wherein the iodine compound is an organic iodine compound.

4. The method of claim 3, wherein the organic iodine compound is hydrocarbon iodide.

5. The method of claim 1, wherein a film formation temperature applied when forming the carbon film is 300 to 600 degrees C.

6. The method of claim 1, wherein the hydrocarbon-based carbon source gas is a hydrocarbon-containing gas expressed as at least one of the following molecular formulas:
CₙH₂ₙ₊₂;
CₘH₂ₘ; and
CₘH₂ₘ₋₂
(where n is a natural number of one or more and m is a natural number of two or more).

7. The method of claim 1, further comprising:
before forming the carbon film, forming a seed layer for shortening an incubation time of the carbon film on the workpiece.

8. The method of claim 7, wherein the forming a seed layer is performed by supplying an aminosilane-based gas into the process chamber and adsorbing the aminosilane-based gas on to a surface of the workpiece.

9. The method of claim 1, wherein the workpiece includes a silicon film formed thereon and the carbon film formed on the silicon film.

10. An apparatus of forming a carbon film on a workpiece, comprising:
a process chamber configured to accommodate the workpiece on which the carbon film is to be formed;
a process gas supply mechanism configured to supply a process gas into the process chamber;
a heating device configured to heat the workpiece accommodated in the process chamber;
a loading mechanism configured to load the workpiece into the process chamber; and
a control part configured to control the process gas supply mechanism, the heating device, and the loading mechanism such that the method of claim 1 is performed.

11. A non-transitory computer-readable storage medium storing a program that operates on a computer and controls a carbon film forming apparatus,
wherein the program, when executed, causes the computer to control the carbon film forming apparatus so as to perform the method of claim 1.
